(19) United States
(12) Patent Application Publication
(10) Pub. No.: US 2023/0232541 A1
(43) Pub. Date: Jul. 20, 2023

(54) APPLICATION METHOD OF FLEXIBLE LED VEHICLE-MOUNTED DISPLAY

(71) Applicant: Shenzhen Juntong Technology Co., Ltd., Shenzhen (CN)

(72) Inventors: JUN ZHAO, Yibin (CN); WEI CUI, Neijiang (CN); SHUN YANG, Chongqing (CN); YUFENG XIONG, Jiujiang (CN); SENLIN JIAN, Chaozhou (CN)

(21) Appl. No.: 17/728,917

(22) Filed: Apr. 25, 2022

(30) Foreign Application Priority Data
Jan. 17, 2022 (CN) 202210047254.3

(51) Int. Cl. H05K 3/30; H05K 1/18; H05B 47/19; G10L 15/22

(52) U.S. Cl. CPC H05K 3/303; G10L 15/22; H05B 47/19; H05K 1/181; H05K 1/189; G10L 2015/223; H05K 2201/10106

(57) ABSTRACT

A bowl can be adsorbed on the table top, comprises a bowl body, a notch is opened at the bottom of the bowl body, a silicone suction cup is arranged in the notch, the silicone suction cup is protruding downward of the bowl body by a predetermined length, the silicone suction cup is used for adsorbing the table top, the bottom of the bowl body abuts on the table top. Based on the above structure, the bottom of the bowl body abuts against the table top closely, so that the gap between the bowl body and the silicone suction cup is hidden in the notch, the user cannot touch the silicone suction cup, the fingers cannot be inserted into the gap between the bowl body and the silicone suction cup, which greatly improves the adsorption stability of the bowl.

### CROSS-REFERENCE TO RELATED APPLICATIONS

This application claims priority to Chinese Patent Application No. 202210047254.3, filed on Jan. 17, 2022, the contents of which are herein incorporated by reference in their entireties.

### TECHNICAL FIELD

The present disclosure relates to the technical field of vehicle-mounted display, in particular to an application method of flexible LED vehicle-mounted display.

### BACKGROUND

There are two types of on-board monitors: one is a TV placed on the bus to watch, which is essentially a vehicle-mounted TV, and the other is a small-sized on-board monitor with 3.5 inches, 4.3 inches, 7 inches and 9 inches. Generally, there are two channels of video input, one way can be connected to vehicle-mounted DVD, the other way can be connected to vehicle-mounted camera for reversing image.

Existing vehicle-mounted display are more common in buses and taxis, all of which are hard materials, not only heavy, but also very inconvenient to install. They are only used for advertising on some special vehicles. In fact, individual consumers really hope to have a display that can be applied to their car to show their personality. Therefore, some companies have reduced the size of the hard screen and fixed it with suction cups, which basically meets the display needs. Just old wine in a new bottle, the display screen is also a hard display screen, which is heavy and cannot be bent, and the essence remains unchanged. The application of hard screen in automobiles mainly has the following disadvantages:

1. The car glass, whether it is the front or rear glass, has a certain curvature, and the display screen of hard material cannot be installed in place.

2. The glass itself has a certain mirror effect. If it cannot be perfectly matched, the light of the display screen will be reflected to the cab by the glass, causing interference to the driver.

3. The hard screen is very heavy, and it is difficult to maintain it for a long time by using the suction cup method. Even if it can be fixed, it is heavy, and it is very easy to tear off the explosion-proof film on the glass.

4. The hard screen will break the glass and cause secondary danger in some traffic emergencies.

5. Since the hard screen cannot be bent, the packaging volume will be large or long, and the transportation will be very complicated and expensive.

### SUMMARY

In order to achieve the above purpose, the present disclosure provides a following technical solutions: an application method of flexible LED vehicle-mounted display, comprises:
using FPC as the basic material of a display main body;
mounting LED lamp beads, display MCU and driver IC on FPC circuit board by the SMD process;
covering surface of the display main body with a protective film;
connecting the display main body and a controller by a connector;
connecting user’s intelligent terminal by the controller;
controlling the controller by a remote controller.

As a technical solution of the present disclosure, the display main body mainly uses FPC as the basic material. Considering the lines that may be damaged during the bending process, when designing the circuit schematic diagram and FPC circuit board, optimize the design to avoid the bending and vulnerable positions to install electronics components.

As a technical solution of the present disclosure, the block of mounting LED lamp beads, display MCU and driver IC on FPC circuit board by the SMD process comprises: pasting a steel sheet on one side of the FPC circuit board to avoid bending and vulnerable lines.

As a technical solution of the present disclosure, the block of covering surface of the display main body with a protective film comprises: mixing A glue and B glue in a ratio of 1:1 to make PU glue or silicon gel, and covering surface of the display main body with the PU glue or silica gel to realize the anti-scratch and waterproof effect of the main body of the display screen

As a technical solution of the present disclosure, the block of connecting the display main body and a controller by a connector comprises: connecting one end of the FPC circuit board on the display main body to the controller by the connector, the controller is internally arranged with a control module and a wireless communication module.

As a technical solution of the present disclosure, the wireless communication module comprises a terminal connection module and a remote control module; and the terminal connection module is one of a Bluetooth transceiver module, a WIFI communication module and a 4G communication module, the remote control module is one of 2.4G radio frequency module and RF433 wireless module.

As a technical solution of the present disclosure, the block of connecting user’s intelligent terminal by the controller comprises: the user’s intelligent terminal invokes the Bluetooth and WIFI of the intelligent terminal to wirelessly connect with the terminal connection module by an APP software, and the intelligent terminal sends the content to be displayed and setting instructions to the wireless communication module by the APP, and the wireless communication module convert and sent to the display main body by the control module, so as to display the content required by the user.

As a technical solution of the present disclosure, the block of controlling the controller by a remote controller comprises:

the remote controller is wirelessly connected to the remote control module by a 2.4G radio frequency module and an RF433 wireless module, and the remote control is one of a buttons remote controller and a voice remote controller;

the controller is quickly controlled by the buttons of a button remote controller, and the button remote controller has its own battery and can be installed on the steering wheel or console of the vehicle;

a voice control command is received through the voice remote controller, and then converted and sent to the display main body through the control module.

As a technical solution of the present disclosure, the casing of the controller is sealed with waterproof glue, and the thickness of the display main body is less than 3 mm.

As a technical solution of the present disclosure, the connector is a waterproof butt male and female plug, which realizes the water proofing between the FPC circuit board and the controller.

Compared with the prior art, the present disclosure provides an application method of flexible LED vehicle-mounted display, which has the following beneficial effects:

The application method of flexible LED vehicle-mounted display, compared with the conventional vehicle-mounted screen, the flexible vehicle-mounted screen not only solves the shortcomings of the hard screen, such as tearing the protective film, bulkiness, light leakage, and insecurity, but also can be bent at will, showing a variety of shapes, the appearance is more diverse and more beautiful than the hard screen, the flexible vehicle-mounted screen, compared with the traditional hard screen, is lighter in weight, more suitable for long-distance transportation, especially suitable for the field of cross-border trade.

### BRIEF DESCRIPTION OF DRAWINGS

FIG. 1 is a schematic flowchart of an application method of flexible LED vehicle-mounted display proposed by the present disclosure.

FIG. 2 is a structure schematic of the display main body of an application method of flexible LED vehicle-mounted display proposed by the present disclosure.

FIG. 3 is a schematic diagram of system control of an application method of flexible LED vehicle-mounted display proposed by the present disclosure.

In the drawings: 1. Display main body; 2. Connector; 3. Controller; 4. Charging data cable

### DETAILED DESCRIPTION

The technical solutions in the embodiments of the present disclosure will be clearly and completely described below with reference to the accompanying drawings in the embodiments of the present disclosure. Obviously, the described embodiments are only a part of the embodiments of the present disclosure, but not all of the embodiments. Based on the embodiments of the present disclosure, all other embodiments obtained by those of ordinary skill in the art without creative efforts shall fall within the protection scope of the present disclosure.

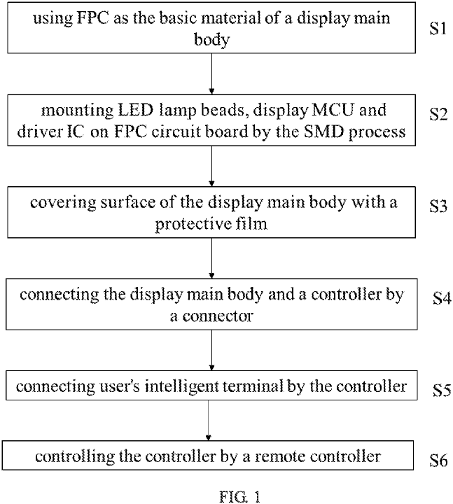

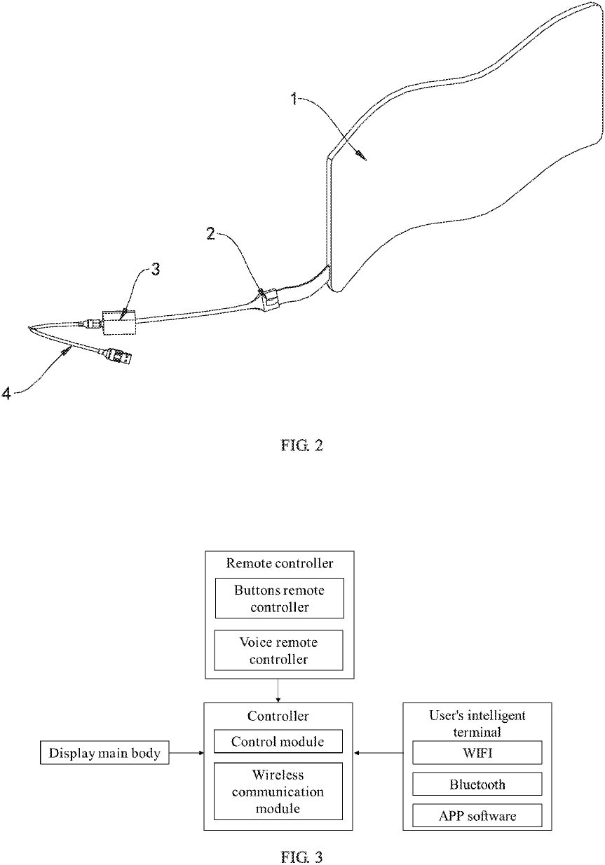

Please refer to FIGS. 1-3, application method of flexible LED vehicle-mounted display, comprises:
S1: using FPC as the basic material of a display main body 1;
S2: mounting LED lamp beads, display MCU and driver IC on FPC circuit board by the SMD process;
S3: covering surface of the display main body 1 with a protective film;
S4: connecting the display main body 1 and a controller 3 by a connector 2;
S5: connecting user’s intelligent terminal by the controller 3;
S6: controlling the controller by a remote controller 3.

As a technical solution of the present embodiment, in the S1, the display main body mainly uses FPC as the basic material. Considering the lines that may be damaged during the bending process, when designing the circuit schematic diagram and FPC circuit board, optimize the design to avoid the bending and vulnerable positions to install electronics components.

As a technical solution of the present embodiment, in the S2, Paste the LED lamp beads, the display MCU and the driver IC on the FPC circuit board using the SMD process, and then paste the steel sheet on one side of the FPC circuit board to avoid bending and vulnerable lines. The function of the steel sheet is to protect the IC part, the IC is not damaged when it is bent, the bending of the IC part is reduced, and it also has the effect of heat dissipation.

As a technical solution of the present embodiment, in the S3, mixing A glue and B glue in a ratio of 1:1 to make PU glue or silicon gel. The surface of the display screen main body 1 is covered with soft PU glue and silica gel through the glue-dropping technology, so as to realize the anti-scratch and waterproof functions of the display screen main body 1, and effectively prevent the water vapor from the inside of the vehicle and external environmental factors from entering the display screen. Inside the screen main body 1, the service life of the display screen main body 1 is guaranteed.

As a technical solution of the present embodiment, in the S4, connecting one end of the FPC circuit board on the display main body 1 to the controller 3 by the connector 2, the controller 3 is internally arranged with a control module and a wireless communication module. The wireless communication module comprises a terminal connection module and a remote control module; and the terminal connection module is one of a Bluetooth transceiver module, a WIFI communication module and a 4G communication module, the remote control module is one of 2.4G radio frequency module and RF433 wireless module. The Bluetooth transceiver module, WIFI communication module and 4G communication module are the current mainstream wireless data transmission modules, which further ensures the usability of the device. The 2.4G radio frequency module and the RF433 wireless module are the current mainstream command transmission modules, with low energy consumption.

As a technical solution of the present embodiment, in the S5, the user’s intelligent terminal invokes the Bluetooth and WIFI of the intelligent terminal to wirelessly connect with the terminal connection module by an APP software, and the intelligent terminal sends the content to be displayed and setting instructions to the wireless communication module by the APP, and the wireless communication module convert and sent to the display main body 1 by the control module, so as to display the content required by the user.

As a technical solution of the present embodiment, in the S6, the remote controller is wirelessly connected to the remote control module by a 2.4G radio frequency module and an RF433 wireless module, and the remote control is one of a buttons remote controller and a voice remote controller; the controller 3 is quickly controlled by the buttons of a button remote controller, and the button remote controller has its own battery and can be installed on the steering wheel or console of the vehicle; a voice control command is received through the voice remote controller, and then converted and sent to the display main body 1 through the control module. Such as need to cut the queue, need help and other shortcut commands, which is convenient for users to use

As a technical solution of the present disclosure, the casing of the controller 3 is sealed with waterproof glue, and the thickness of the display main body is less than 3 mm. The connector 2 is a waterproof butt male and female plug, which realizes the water proofing between the FPC circuit board and the controller 3. The display main body 1 and the controller 3 adopt UART protocol serial communication, adopt 4PIN waterproof male and female plugs, and the way of plug-in connection, which is detachable and convenient for later installation.

In summary, the application method of flexible LED vehicle-mounted display, compared with the conventional vehicle-mounted screen, the flexible vehicle-mounted screen not only solves the shortcomings of the hard screen, such as tearing the protective film, bulkiness, light leakage, and insecurity, but also can be bent at will, showing a variety of shapes, the appearance is more diverse and more beautiful than the hard screen, the flexible vehicle-mounted screen, compared with the traditional hard screen, is lighter in weight, more suitable for long-distance transportation, especially suitable for the field of cross-border trade.

It should be noted that, herein, terms such as “comprises”, “comprising” or any other variation thereof are intended to encompass non-exclusive inclusion, such that a process, method, article or device comprising a series of elements includes not only those elements, but also other elements not expressly listed or inherent to such a process, method, article or apparatus. Without further limitation, an element qualified by the phrase “comprising a...” does not preclude the presence of additional identical elements in a process, method, article or apparatus that includes the element.

Although embodiments of the present disclosure have been shown and described, it will be understood by those skilled in the art that various changes, modifications, and substitutions can be made in these embodiments without departing from the principle and spirit of the invention and modifications, the scope of the present disclosure is defined by the appended claims and their equivalents.

What is claimed is:

1. An application method of flexible LED vehicle-mounted display, comprising:
using FPC as the basic material of a display main body;
mounting LED lamp beads, display MCU and driver IC on FPC circuit board by the SMD process;
covering surface of the display main body with a protective film;
connecting the display main body and a controller by a connector;
connecting user’s intelligent terminal by the controller;
controlling the controller by a remote controller.

2. The application method of flexible LED vehicle-mounted display according to claim 1, wherein further comprises:
installing electronic components on the FPC circuit avoid bending and vulnerable position.

3. The application method of flexible LED vehicle-mounted display according to claim 1, wherein the block of mounting LED lamp beads, display MCU and driver IC on FPC circuit board by the SMD process comprises:
pasting a steel sheet on one side of the FPC circuit board to avoid bending and vulnerable lines.

4. The application method of flexible LED vehicle-mounted display according to claim 1, wherein the block of covering surface of the display main body with a protective film comprises:
mixing A glue and B glue in a ratio of 1:1 to make PU glue or silicon gel, and covering surface of the display main body with the PU glue or silica gel.

5. The application method of flexible LED vehicle-mounted display according to claim 1, wherein the block of connecting the display main body and a controller by a connector comprises:
connecting one end of the FPC circuit board on the display main body to the controller by the connector, the controller is internally arranged with a control module and a wireless communication module.

6. The application method of flexible LED vehicle-mounted display according to claim 5, wherein the wireless communication module comprises a terminal connection module and a remote control module; and the terminal connection module is one of a Bluetooth transceiver module, a WIFI communication module and a 4G communication module, the remote control module is one of 2.4G radio frequency module and RF433 wireless module.

7. The application method of flexible LED vehicle-mounted display according to claim 1, wherein the block of connecting user’s intelligent terminal by the controller comprises:
the user’s intelligent terminal invokes the Bluetooth and WIFI of the intelligent terminal to wirelessly connect with the terminal connection module by an APP software, and the intelligent terminal sends the content to be displayed and setting instructions to the wireless communication module by the APP, and the wireless communication module convert and sent to the display main body by the control module, so as to display the content required by the user.

8. The application method of flexible LED vehicle-mounted display according to claim 1, wherein the block of controlling the controller by a remote controller comprises:
the remote controller is wirelessly connected to the remote control module by a 2.4G radio frequency module and an RF433 wireless module, and the remote control is one of a buttons remote controller and a voice remote controller;
the controller is quickly controlled by the buttons of a button remote controller, and the button remote controller has its own battery and can be installed on the steering wheel or console of the vehicle;
a voice control command is received through the voice remote controller, and then converted and sent to the display main body through the control module.

9. The application method of flexible LED vehicle-mounted display according to claim 1, wherein the casing of the controller is sealed with waterproof glue, and the thickness of the display main body is less than 3 mm.

10. The application method of flexible LED vehicle-mounted display according to claim 1, wherein the connector is a waterproof butt male and female plug, which realizes the water proofing between the FPC circuit board and the controller.
